(19) United States
(12) Patent Application Publication
(10) Pub. No.: US 2009/0108433 A1
(43) Pub. Date: Apr. 30, 2009

(54) MULTILAYER SEMICONDUCTOR DEVICE PACKAGE ASSEMBLY AND METHOD

(76) Inventors: Kenji Masumoto, Hayami-gun (JP); Kazuaki Ano, Hayami-gun (JP)

Correspondence Address: TEXAS INSTRUMENTS INCORPORATED, P O BOX 655474, M/S 3999, DALLAS, TX, 75265, US

(21) Appl. No.: 11/928,172

(22) Filed: Oct. 30, 2007

(51) Int. Cl. H01L 23/48; H01L 21/66

(52) U.S. Cl. 257/690; 438/15; 257/E21.529; 257/E23.01

(57) ABSTRACT

Methods for assembling multilayer semiconductor device packages are disclosed. A base substrate having device mounting sites is provided. A number of semiconductor devices are connected to the device mounting sites. Upper boards are attached to the base substrate and over each of the coupled devices. The method includes steps of testing one or more of the base substrate, semiconductor device, or upper board, prior to operably connecting one to another.

### TECHNICAL FIELD

The invention relates to electronic semiconductor devices and manufacturing. More particularly, the invention relates to multilayer microelectronic semiconductor device packages having vertically stacked semiconductor device components, and to methods for their assembly.

### BACKGROUND OF THE INVENTION

It is known in the art to construct a vertically stacked semiconductor device package using a build-up process. In general, such processes rely on sequentially assembling stack components, with significant modifications to at least some of the components on site. Conventionally, a bottom substrate layer has an area prepared to receive an IC (integrated circuit) or other semiconductor device, typically attached using micro bumps or solder. In a process not unlike conventional PCB (printed circuit board) build-up, one or more additional substrate layers are subsequently attached to the bottom layer adjacent to the attached semiconductor device. This intermediate layer typically has a “window” opening for aligning with the IC. Each layer, and the intermediate layer in particular, may be patterned, etched, plated, coated, mechanically or laser drilled, or otherwise modified, subsequent to attachment according to system requirements for making inter-layer and intra-layer electrical connections. Often, vias drilled through intermediate layers are filled with metal for making electrical connections between surrounding layers. Eventually, an upper layer is attached spanning the surface of the semiconductor device and adjacent materials. The surface of this upper layer may also be further modified, e.g., plated, drilled, coated, et cetera, in order to facilitate coupling to additional chips, boards, wires, or packages.

An ever-present problem in the semiconductor arts generally is the need to increase manufacturing yield. A significant drawback to the build-up processes commonly used in the arts for stacked semiconductor device package assembly is a the interdependence of the sequential steps. Due to the sequential nature of such a process, the assembly yield is more-or-less the product of the yields of each process step. As a result, time and materials committed to a particular assembly may be lost due to defects introduced at any other step in the process. For example, a package assembly in which an IC, other materials, and significant time and effort have been invested, may ultimately be lost due to defects introduced in the step of mechanically drilling or laser drilling through an intermediate layer, in filling vias, or in the steps of coating the surface of the final layer of the assembly.

Due to these and other technological challenges, improved semiconductor device package assemblies with embedded semiconductor devices and related methods for reducing process yield risks would be useful and advantageous in the arts. The present invention is directed to overcoming, or at least reducing the effects of one or more of the problems existing in the art.

### SUMMARY OF THE INVENTION

In carrying out the principles of the present invention, in accordance with preferred embodiments thereof, the invention provides methods for assembling multilayer semiconductor device packages using a non-sequential approach for improving process yields.

According to one aspect of the invention, a method for assembling a multilayer semiconductor device package includes steps for providing a base substrate having a plurality of device mounting sites and a plurality of contact pads adjacent to the device mounting sites. Semiconductor devices are connected to the mounting sites using metallurgical joints. An upper board is attached over each of the mounted devices and operably coupled to the base substrate using metallurgical joints as well. Further steps are included for testing one or more of the base substrate, semiconductor device, or upper board, prior to connecting one to another.

According to other aspects of the invention, in a preferred embodiment, the steps include testing at least one combination of base substrate and/or semiconductor device and/or upper board, prior to connecting one to another.

According to another aspect of the invention, a preferred embodiment includes affixing an upper board sheet including multiple upper boards over multiple semiconductor devices mounted on the base substrate.

According to another aspect of the invention, a method for assembling a multilayer semiconductor device package includes a series of steps for providing a base substrate with numerous semiconductor device mounting sites and then mounting semiconductor devices thereupon. Upper boards are affixed over the semiconductor devices. Underfill material is added to fill gaps between the package elements, and individual multilayer semiconductor device packages are singulated from adjoining packages assembled on the base substrate.

According to yet another aspect of the invention, in preferred embodiments, one or more combinations of multilayer semiconductor device package elements are tested during the assembly process, prior to the continuation of the assembly process.

According to still another aspect of the invention, in an example of preferred embodiments, a step is included for testing one or more of the combinations of operably coupled mounting site, semiconductor device, and upper board, prior to interposing dielectric underfill material between elements of the assembly.

The invention has advantages including but not limited to increasing manufacturing yields and reducing costs for multilayer stacked or embedded semiconductor device assemblies. These and other features, advantages, and benefits of the present invention can be understood by one of ordinary skill in the applicable arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1A is a cutaway partial side view of package assembly elements and steps in an example of a preferred embodiment of the invention;

FIG. 1B is a cutaway partial side view of package assembly elements and further steps in an example of a preferred embodiment of the invention;

FIG. 1C is a cutaway partial side view of package assembly elements and further steps in an example of a preferred embodiment of the invention;

FIG. 1D is a cutaway partial side view of further steps and of an example of a package assembly according to a preferred embodiment of the invention;

FIG. 2 is a perspective view of package assemblies, elements, and method steps in another example of preferred embodiments of the invention;

FIG. 3A is a perspective view of package assembly elements and steps in an alternative example of a preferred embodiment of the invention; and

FIG. 3B is a perspective view of package assembly elements and further steps in a continuation of the example of a preferred embodiment of the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of the embodiments shown and described are simplified or amplified for illustrating the principles, features, and advantages of the invention.

### DESCRIPTION OF PREFERRED EMBODIMENTS

The invention provides multilayer semiconductor device package assembly methods wherein the elements of the package may be tested independently and in various combinations before completion of the final assembly. Preferably, each element of the package is functionally tested before assembly to increase yield, reducing the risk of the loss of package elements and process time due to incorporating defective elements into a package assembly. Process steps or package elements may be omitted or replaced, individually or collectively, in the event of defective elements or combinations of elements revealed by ongoing testing during the assembly process.

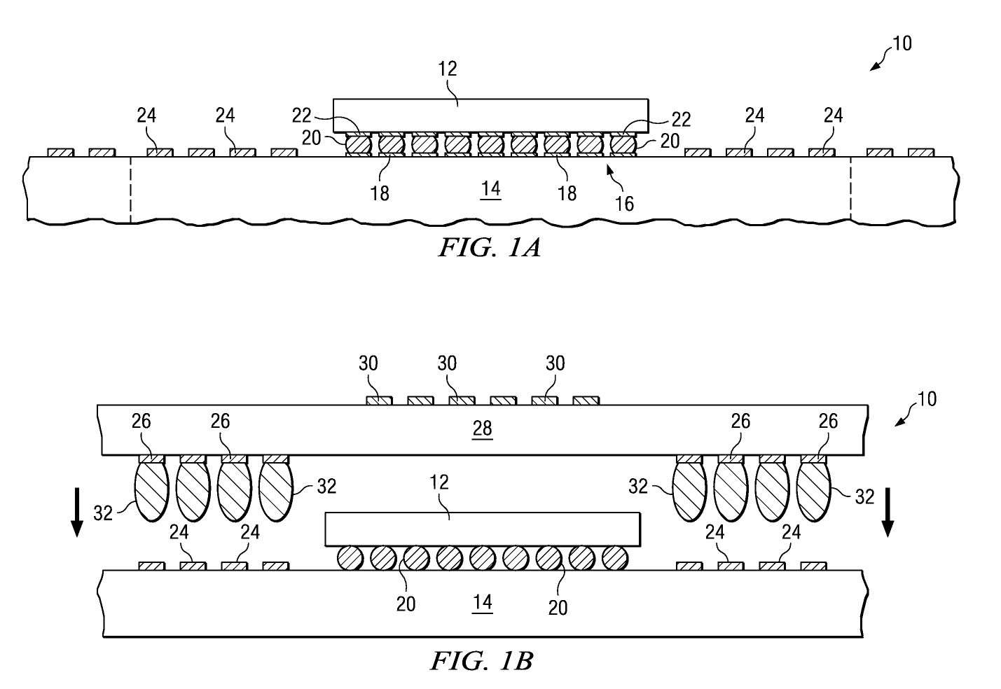

A multilayer package assembly 10 with an embedded semiconductor device 12 is depicted in various stages of completion showing assembly method steps in FIGS. 1A through 1D. The semiconductor device 12 is preferably an IC, but the invention may also be practiced in various ways and with other semiconductor device types and combinations of package elements such as passive circuit components, PCBs, PWBs, or packaged chip assemblies. Referring first to FIG. 1A, a cutaway partial side view shows initial steps in the assembly of a multilayer semiconductor device package assembly 10 in a preferred embodiment of the invention. A base substrate 14 is provided with a semiconductor device mounting site 16 prepared for receiving a semiconductor device 12. The mounting site 16 typically includes suitable contacts 18 as known in the arts for completing operable electrical connections 20 between the base substrate 14 and contacts 22 on the semiconductor device 12, preferably using micro bumps 20 or solder balls. A number of contact pads 24 are also preferably provided adjacent to the semiconductor device mounting site 16.

Now referring primarily to FIG. 1B, it can be seen that the contact pads 24 of the base substrate 14 may be aligned with corresponding contact pads 26 on an upper board 28 configured for placement overlaying both the base substrate 14 and intervening semiconductor device 12. Preferably, the upper board 28 is a multilayer semiconductor device, e.g., PCB, or PWB, which includes conductive electrical traces (not shown) for making electrical connections with the base substrate 14 such that the semiconductor device 12, base substrate 14, upper board 28, any additional devices (not shown) potentially added to the upper board 28, may operate in concert. The upper board 28 preferably also includes exposed contacts 30 on its outer surface for accepting additional electrical connections. The upper board 28 contacts 26 and base substrate 14 contact pads 24 are preferably joined using metallurgical joints, such as micro bumps, or solder balls 32, as shown in FIG. 1C. Preferably, the metallurgical joints are made using fine-pitch solder ball arrays, for example, 0.40 mm or smaller pitch. Thus, no drilling or filling of intermediate layers is used for making operable electrical connections between the base substrate 14 and upper board 28.

An assembled multilayer (e.g., base substrate 14, upper board 28, embedded semiconductor device 12,) package 10 is portrayed in FIG. 1D. Underfill material 34 is preferably interposed into gaps in the structure 10, in this case between the base substrate 14 and the upper board 28, between the semiconductor device 12 and the upper board 28, and between the base substrate 14 and the semiconductor device 12. The underfill material 34 preferably plays a role in strengthening the package 10 as well as sealing the interior. External solder balls 36 may also be attached in order to facilitate mounting the multilayer package assembly 10 to another assembly, board, or device (not shown). It should be appreciated that the base substrate 14, semiconductor device 12, and upper board 28 are preferably fabricated, tested, and prepared for assembly independent of one another in order to increase the yield of the assembly process. Further testing may also be performed at various stages during assembly as well, for example, testing the semiconductor device 12 and base substrate 14 combination prior to attaching the upper board 28. Preferably, the elements of the package 10 are tested, either individually or using sampling, using testing techniques known in the arts. Thus increased yields may be achieved through ensuring the use of non-defective package elements and by avoiding the performance of manufacturing steps, e.g., drilling and filling, on elements after installation in the package assembly.

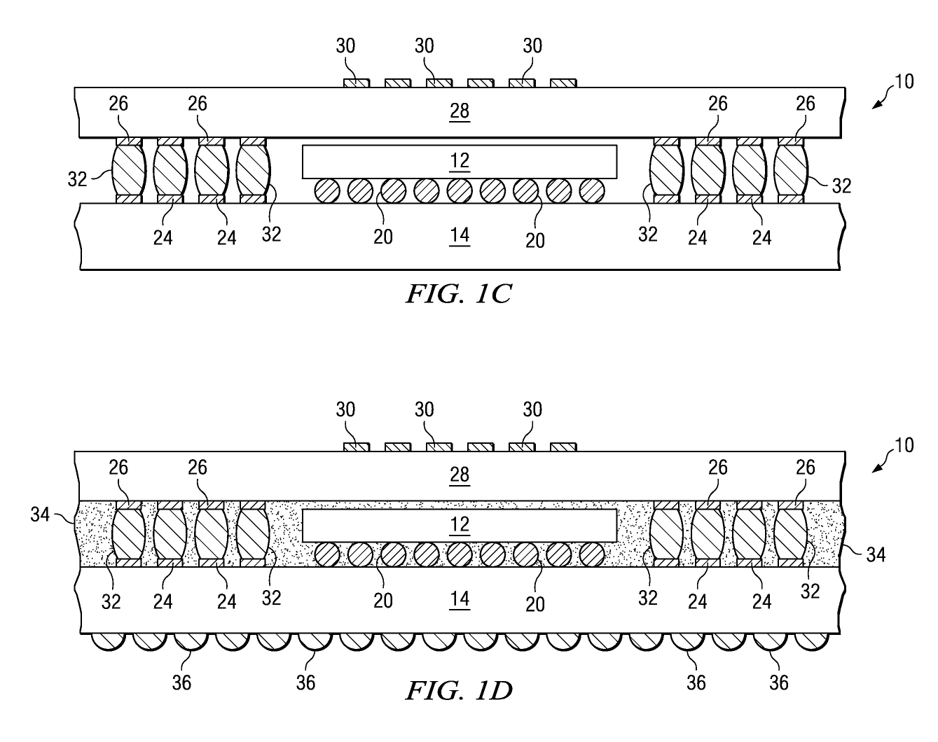

An alternative depiction of an example of one of the preferred embodiments of the invention is shown in FIG. 2. The base substrate 14 preferably has numerous semiconductor device mounting sites 16 prepared for receiving individual semiconductor devices 12. The sites 16 include contacts 18 for completing operable electrical connections among points within the base substrate 14 and the semiconductor device 12, preferably using micro bumps or solder balls. Contact pads 24 are also preferably provided adjacent to the device mounting sites 16. Numerous individual upper boards 28 may be independently prepared in a configuration for placement over each mounted semiconductor device 12, and adjacent contacts 24, on the base substrate 14. Preferably, each upper board 28 includes electrical traces (not shown) for making electrical connections with the base substrate 14 such that the semiconductor device 12, base substrate 14, and upper board 28, may operate in concert. Preferably, the upper boards 28 are joined to the underlying layer, e.g. base substrate 14 with devices 12, using suitable metallurgical joints 32, such as micro bumps, or solder balls. Assembled multilayer semiconductor device packages 10 may be completed by underfilling, around the edges 38 of the semiconductor devices 12, for example, and ultimately by singulation between the package assemblies 10. It should be appreciated that the base substrate 14, semiconductor devices 12, and upper boards 28 are preferably fabricated, tested, and prepared for assembly independent of one another in order to reduce waste and/or increase the yield of the assembly process. Further testing may also be performed at various stages during the assembly process. For example, as shown reference numeral 40, if a particular semiconductor device mounting site 40 tests defective, the semiconductor device and upper board may be omitted from that site 40. In another example, shown at reference numeral 42, if a particular semiconductor device and mounting site combination 42 tests defective, the upper board may be omitted from that combination 42.

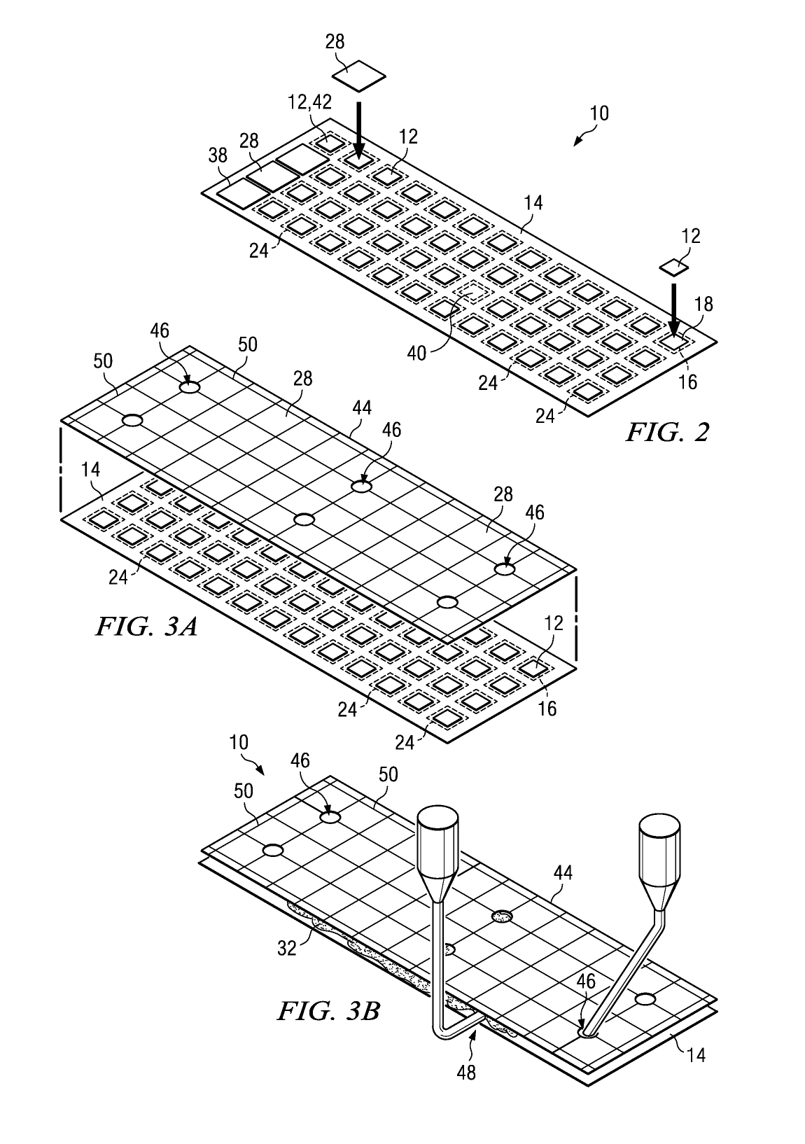

An example of an alternative preferred embodiment of the invention is shown in FIGS. 3A and 3B. As shown in these perspective views, a base substrate 14 is preferably provided with a number of semiconductor mounting sites 16 prepared for receiving semiconductor devices 12 for permanent mounting. As shown, the upper boards 28 are preferably prepared as a single upper board sheet 44 for application to the base substrate 14 and numerous attached semiconductor devices 12. The upper board sheet 44 having a number of individual upper boards 28 arrayed on its surface, including upper contact pads 26 arranged to correspond with the semiconductor devices 12 and contact pads 24 on the base substrate 14. Subsequent to the joining of the semiconductor devices 12, base substrate 14, and upper board sheet 44, preferably using solder joints as described above, the packages 10 are typically sealed using underfill material 34, either through apertures 46 provided in one or more of the layers, e.g., the upper board sheet 44, or flowed in through one or more edges 48, or by a suitable combination of underfilling techniques known in the art. The individual packages 10 are ultimately singulated from one another using techniques familiar in the arts, such as sawing along saw streets 50 preferably provided for this purpose at appropriate locations. As indicated with reference to other embodiments of the invention, it should be appreciated that the base substrate 14, semiconductor devices 12, and board sheet 44 or individual upper boards 28, may be preferably fabricated, tested, and prepared for assembly independent of one another in order to identify defects at any given point which may be perceived as advantageous for increasing the yield of the particular assembly process with which the invention is practiced.

The invention provides one or more advantages including but not limited to reducing waste, increasing process efficiency by avoiding the performance of assembly steps using defective components, and increasing yield. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A method for assembling a multilayer semiconductor device package comprising the steps of:
providing a base substrate, the base substrate having a plurality of semiconductor device mounting sites and a plurality of contact pads adjacent to the semiconductor device mounting sites;
operably coupling a plurality of semiconductor devices to a plurality of the semiconductor device mounting sites using metallurgical joints;
affixing an upper board over each of the coupled devices, the upper boards each having a plurality of contacts arranged to correspond to contact pads on the base substrate, whereby a plurality of the upper board contacts are operably coupled to the base substrate contact pads using metallurgical joints;
wherein the method further comprises the step of testing one or more of the base substrate, semiconductor devices, and upper boards, prior to operably coupling; and
singulating individual multilayer semiconductor device packages from adjoining multilayer semiconductor device packages.

2. The method according to claim 1 further comprising the step of testing one or more base substrate and coupled semiconductor device in combination prior to affixing an upper board to the semiconductor device.

3. The method according to claim 1 further comprising the step of interposing dielectric underfill material between the semiconductor devices and the base substrate.

4. The method according to claim 1 further comprising the step of interposing dielectric underfill material between the base substrate and the upper boards.

5. The method according to claim 1 further comprising the step of providing an upper board having electrical contacts on an exposed surface for making operable electrical connections subsequent to affixing over a semiconductor device.

6. The method according to claim 1 further comprising the step of singulating a plurality of multilayer semiconductor device packages from the base substrate subsequent to the affixing step.

7. The method according to claim 1 wherein the step of affixing an upper board over each of the coupled semiconductor devices further comprises affixing an upper board sheet over a plurality of the semiconductor devices, the upper board sheet having a plurality of individual boards arranged on a continuous sheet, the individual boards having contacts arranged to correspond to contact pads on the base substrate.

8. The method according to claim 1 wherein the step of affixing an upper board over each of the coupled semiconductor devices further comprises affixing a plurality of individual upper boards over a plurality of the devices, each upper board having a plurality of contacts arranged to correspond to contact pads on the base substrate.

9. A method for assembling a multilayer semiconductor device package comprising the steps of:
providing a base substrate, the base substrate having a plurality of semiconductor device mounting sites and a plurality of contact pads adjacent to the semiconductor device mounting sites;
operably coupling a plurality of semiconductor devices to a plurality of the semiconductor device mounting sites using metallurgical joints;
affixing an upper board over each of the plurality of semiconductor devices, each upper board having a plurality of contacts arranged to correspond to contact pads on the base substrate, whereby a plurality of the upper board contacts are operably coupled to the base substrate contact pads using metallurgical joints;
interposing dielectric underfill material between the base substrate and the upper boards;
thereby forming a plurality of adjoining multilayer semiconductor device packages on the base substrate; and
singulating individual multilayer semiconductor device packages from adjoining multilayer semiconductor device packages.

10. The method according to claim 9 further comprising the step of testing one or more of the semiconductor device mounting sites of the base substrate prior to operably coupling semiconductor devices to a plurality of the semiconductor device mounting sites.

11. The method according to claim 9 wherein the step of affixing an upper board over each of the coupled semiconductor devices further comprises affixing an upper board sheet over a plurality of the semiconductor devices, the upper board sheet having a plurality of individual boards arranged on a continuous sheet, the individual boards having contacts arranged to correspond to contact pads on the base substrate.

12. The method according to claim 9 wherein the step of affixing an upper board over each of the coupled semiconductor devices further comprises affixing a plurality of individual upper boards over a plurality of the devices, each upper board having a plurality of contacts arranged to correspond to contact pads on the base substrate.

13. The method according to claim 9 further comprising the step of testing one or more of the semiconductor devices prior to operably coupling semiconductor devices to a plurality of the semiconductor device mounting sites.

14. The method according to claim 9 further comprising the step of testing one or more of the upper boards prior to affixing an upper board over each of the plurality of semiconductor devices.

15. The method according to claim 9 further comprising the step of testing one or more of the combinations of operably coupled semiconductor device to semiconductor device mounting sites, prior to affixing an upper board over each of the plurality of semiconductor devices.

16. The method according to claim 9 further comprising the step of testing one or more of the combinations of operably coupled semiconductor device, to semiconductor device mounting site, with upper board affixed, prior to interposing dielectric underfill material between the base substrate and the upper boards.

17. A method for assembling a multilayer semiconductor device package comprising the steps of:
providing a base substrate, the base substrate having a plurality of semiconductor device mounting sites and a plurality of contact pads adjacent to the semiconductor device mounting sites;
operably coupling a plurality of semiconductor devices to a plurality of the semiconductor device mounting sites using metallurgical joints;
affixing an upper board sheet comprising a plurality of boards over the coupled devices, the upper boards of the upper board sheet each having a plurality of contacts arranged to correspond to contact pads on the base substrate, whereby a plurality of the upper board contacts are operably coupled to the base substrate contact pads using metallurgical joints;
wherein the method further comprises the step of testing one or more of the base substrate, semiconductor devices, and upper boards, prior to operably coupling; and
singulating individual multilayer semiconductor device packages from adjoining multilayer semiconductor device packages.

18. The method according to claim 17 further comprising the step of testing one or more base substrate and coupled semiconductor device in combination prior to affixing an upper board to the semiconductor device.

19. The method according to claim 17 further comprising the step of interposing dielectric underfill material between the semiconductor devices and the base substrate.

20. The method according to claim 17 further comprising the step of interposing dielectric underfill material between the semiconductor devices and the upper board.

21. The method according to claim 17 further comprising the step of providing an upper board having electrical contacts on an exposed surface for making operable electrical connections subsequent to affixing over a semiconductor device.

22. A multilayer semiconductor device package comprising:
a base substrate having a semiconductor device mounting site and a plurality of contact pads adjacent to the semiconductor device mounting site;
a semiconductor device operably coupled to the semiconductor device mounting site;
an upper board affixed over the semiconductor device, the upper board having a plurality of contacts arranged to correspond to contact pads on the base substrate, whereby a plurality of the upper board contacts are operably coupled to the base substrate contact pads using metallurgical joints; and
dielectric underfill material between the base substrate and the upper boards.
